(19) United States
(12) Patent Application Publication
(10) Pub. No.: US 2012/0048614 A1
(43) Pub. Date: Mar. 1, 2012

(54) BACKGROUND OF THE INVENTION

(75) Inventors: ZHANG-LAN XUE, Kunshan (CN); HONG-QIANG HAN, Kunshan (CN); ZI-QIANG ZHU, Kunshan (CN)

(73) Assignee: HON HAI PRECISION INDUSTRY CO., LTD., New Taipei (TW)

(21) Appl. No.: 13/221,806

(22) Filed: Aug. 30, 2011

(30) Foreign Application Priority Data
Sep. 1, 2010 (CN) 201020513067.2

(51) Int. Cl. H05K 5/00

(52) U.S. Cl. 174/520

(57) ABSTRACT

A PV (photovoltaic) junction box comprises a case and a plurality of terminals received within the case. The case has a bottom wall and a plurality of sidewalls located on a peripheral of the bottom wall and defines a receiving cavity cooperatively with the bottom wall. The sidewalls comprise a front wall and two planar connecting sidewalls connecting with the front wall. The connecting sidewall is aslant disposed relative to the front wall, and the case further has an assembling portion outwardly and vertically protruding from each of the connecting sidewall, the assembling portion defines a port of the case for a cable passing through.

### BACKGROUND OF THE INVENTION

1. Field of the Invention

The invention relates to a junction box, especially for a PV (photovoltaic) junction box for connecting to a solar panel.

2. Description of Related Art

Junction boxes are used in a wide variety of technical sectors in order to make electrical connections between electric lines and an electrical device. Solar panels have a large number of solar cells which are used to convert power from sunlight. The power generated by the solar cells is conveyed via electric lines, for example to a rectifier, for feeding into an alternating current (AC) network or to a battery. A PV junction box is generally provided for electrical connection to the lines of the solar panel.

A conventional junction box is known from Chinese patent issue No. CN 201312273, issued on Sep. 16, 2009. The junction box is mounted on a solar panel and connects with other junction box by a cable extending out of the junction box. The junction box comprises a bottom case, a top case covering the bottom case and a plurality of terminals set in the bottom case. The terminals electrically connect to the solar panel at an end there of and electrically connects to the cable at the other end thereof. The bottom case substantially has a box-shaped configuration with four sidewalls and arch transition parts jointing two adjacent sidewalls, and the cable aslant extends out of the junction box from the arch transition part with a 45 degrees angle with respect to a transverse direction, so that the junction box can convenient connect with another junction box beside the junction box without over bending the cable. However, the cable is directly inserts into the junction box through the arch transition part, a gap may appear between an arch surface of the arch transition part and the cable and may influence a waterproof property of the junction box.

Hence, an improved PV junction box is highly desired to overcome the aforementioned disadvantages of the prior art.

### SUMMARY OF THE INVENTION

Accordingly, an object of the present invention is to provide an PV junction box which can provide a well position of a cable connecting to the PV junction box.

To fulfill the above object, a PV junction box comprises a case, a lid covering the case and a plurality terminals. The base has a bottom wall and a plurality of sidewalls located on a peripheral of the bottom wall and defining a receiving cavity cooperatively with the bottom wall, the terminals are received in the receiving cavity of the case. The sidewalls comprise a front wall extending along a right-to-left direction and two planar connecting sidewalls located on two opposite sides of the front wall along the right-to-left direction and connecting with the front wall, respectively, the connecting sidewall is aslant disposed relative to the front wall. The case has an assembling portion outwardly and vertically protruding from each of the connecting sidewall.

Other objects, advantages and novel features of the present invention will be drawn from the following detailed description of a preferred embodiment of the present invention with attached drawings.

### BRIEF DESCRIPTION OF THE DRAWINGS

FIG. 1 is an assembled, perspective view of a PV junction box in accordance with a preferred embodiment of present invention;

FIG. 2 is another assembled, perspective view of the PV junction box, wherein the lid of the junction box is opened;

FIG. 3 is another perspective view of the PV junction box without the lid;

FIG. 4 is an exploded view of the PV junction box;

FIG. 5 is similar with FIG. 4, but taken from another side; and

FIG. 6 is an exploded view of terminals with diodes and clampers of the PV junction box.

### DETAILED DESCRIPTION OF THE INVENTION

Reference will now be made in detail to the preferred embodiment of the present invention.

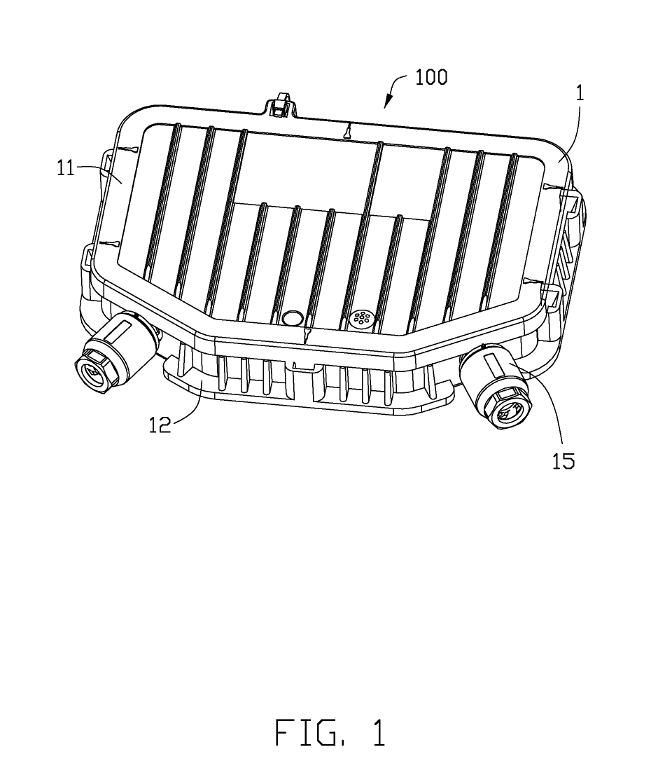

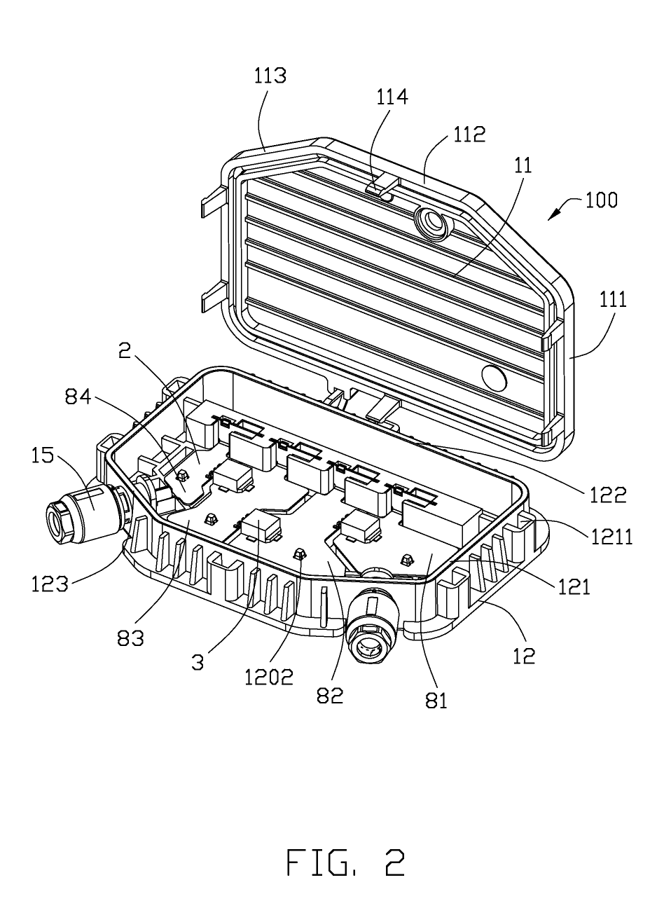

Referring to FIG. 1 and FIG. 2, a PV junction box 100 in accordance with a preferred embodiment of present invention is adapted to connect solar panels and transmit currents. The PV junction box 100 electrically connects with two cables (not shown) and comprises an insulative housing 1, a plurality of terminals 2 secured within the insulative housing 1 to connect the two cables and a plurality of diodes 3.

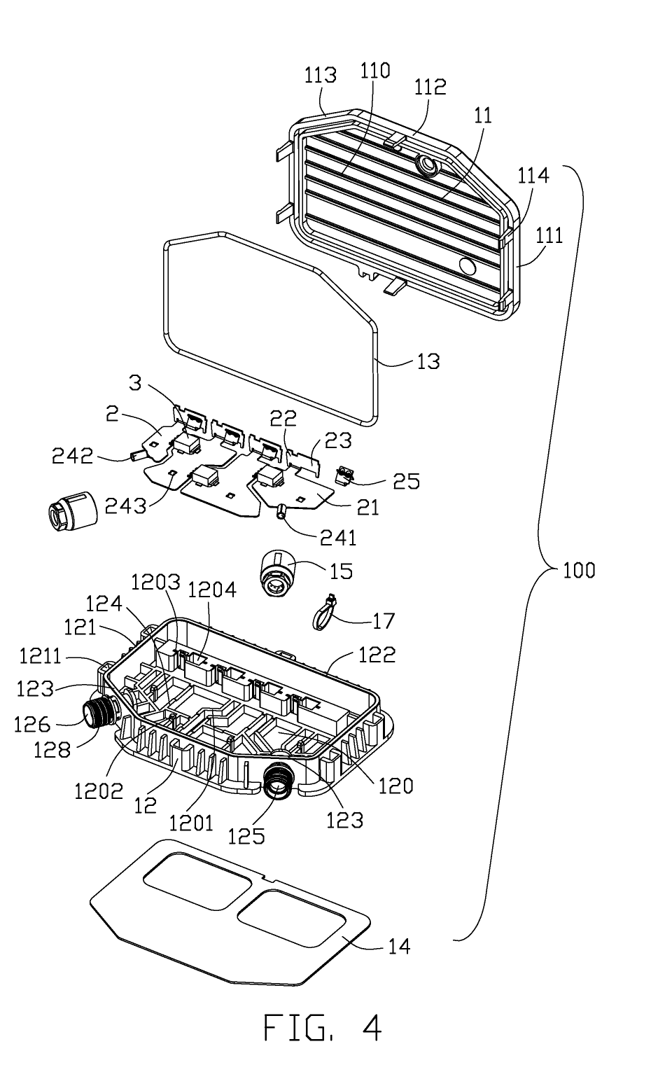

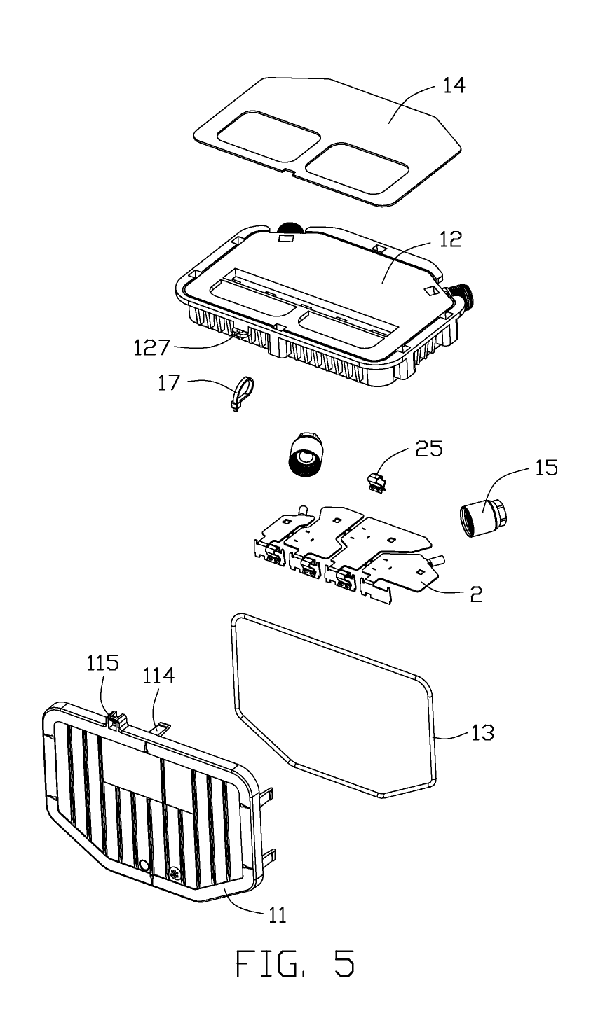

Referring to FIG. 4 and FIG. 5, the insulative housing 1 has a substantial square box shape, and comprises a case 12 and a lid 11 covering the case 12 and a sealing ring 13, an adhesive film 14 mounted to a bottom surface of the case 12 and a tying rope 17 tying the lid 11 and the case 12. The sealing ring 13 substantially is made of silicone or plastic material and sandwiched between the lid 11 and the case 12 to provide a well waterproof function of the PV junction box 100. The adhesive film 14 is used to adhere to the solar panel.

The lid 11 has a top wall 110 and a plurality of side walls extending downwardly from a peripheral of the top wall 110. The side walls include a pair of first outer walls 111 parallel to each other and extending along a front-to-back direction, a pair of second outer walls 112 parallel to each other and extending along a right-to-left direction and two inclined walls 113 provided between one of the second outer walls 112 located in the front of the lid 11 and each of the two first outer walls 111, respectively. The two inclined walls 113 are symmetrical disposed along a transverse or longitude axis of the lid 11. The first and the second outer wall 111, 112 are further formed with a plurality of latching arms 114 downwardly and uprightly extending to latch with the case 12. The second outer wall 112 in the back of the PV junction box 100 is provided with a first hole 115 for the tying rope 17 passing through.

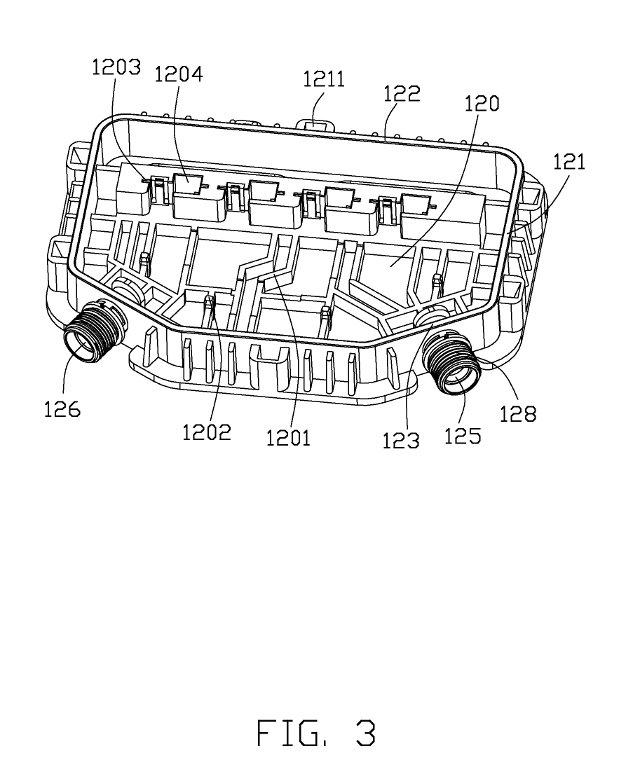

Referring to FIGS. 3-4, the case 12 has a corresponding configuration to that of the lid 11, and comprises a bottom wall 120 and a plurality of sidewalls extending upwardly from a peripheral of the bottom wall 120. The sidewalls include a pair of first sidewalls 121 parallel to each other and extending along the front-to-back direction, a pair of second sidewalls 122 parallel to each other and extending along the right-to-left direction and two planar connecting sidewalls 123 aslant provided between one of the second sidewall 122 located in the front of the case 12 and each of the two first sidewalls 121, respectively. The two connecting sidewalls 123 are symmetrical disposed in a front of the first sidewalls 121, and the position and configuration of the connecting sidewalls 123 are corresponding to that of the inclined wall 113 of the lid 11. The first sidewalls 121, the second sidewalls 122, the connecting sidewalls 123 and the bottom wall 120 cooperatively define a receiving cavity 124 for receiving the terminals 2.

Conjoined with FIG. 2, the bottom wall 120 has a plurality of ribs 1201 for supporting the terminal 2 and a plurality of positioning posts 1202 further upwardly extending to position the terminal 2. The bottom wall 120 defines a plurality of retaining slots 1203 for retaining with the terminal 2 and a plurality of receiving slots 1204 communicating with the latching slot 1203 for receiving clampers 25 at a rear end thereof. The first sidewalls 121 and the second sidewalls 122 of the case 12 are formed with a plurality of latching grooves 1211 for latching with the latching arms 114 of the lid 11. One of the second sidewall 122 located on the rear of the case 12 defines a second hole 127. The tying rope 17 passes through the first hole 115 of the lid 11 and the second hole 127 of the case 12 to tie the lid 11 and the case 12.

An assembling portion 128 protrudes outwardly from the connecting sidewall 123, the cable passes the assembling portion 128 into the receiving cavity 124, one of the assembling portions 128 forms a positive input port 125 on the right, and the other forms a negative output port 126 on the left. The PV junction box 100 has sleeves 15 assembled to the assembling portions 128, the assembling portion 128 defines outer thread, and the sleeve 15 defines inner thread to engage with the outer thread of the assembling portion 128.

Then the cable extends out of the junction box 100 from the assembling portion 128 by an outward inclined manner relative to both the front-to-back direction and the right-to-left direction. When the junction box 100 connects to an adjacent another junction box (not shown) disposed on a side of the junction box 100 whether along a front-to-back direction or the right-to-left direction, the cable will not be over excessively bent which may influence a lift of the cable. The assembling portion 128 is integrally formed with the case 12, no gap will appear between the assembling portion 128 and the connecting sidewall 123, so that the PV junction box 100 is well sealed and has a satisfied waterproof property.

The assembling portion 128 is integrally formed with the case 12 in present embodiment, but also can de discrete with the case 12 in other embodiment. A separated assembling portion 128 is vertically attached to the connecting sidewall 123 and engages with the connecting sidewall 123 in a face-to-face manner to ensure a waterproof of the junction box 100. The connecting sidewall 123 defines a 45 degrees angle to a transverse axis or a longitudinal axis of the case 12, so the assembling portion 128 vertical to the connecting sidewall 123 also defines a 45 degrees angle to the transverse axis or the longitudinal axis of the case 12, but the inclined angle of the connecting sidewall 123 can be various within 0˜90 degrees in other embodiment and decided by a position of adjacent junction box.

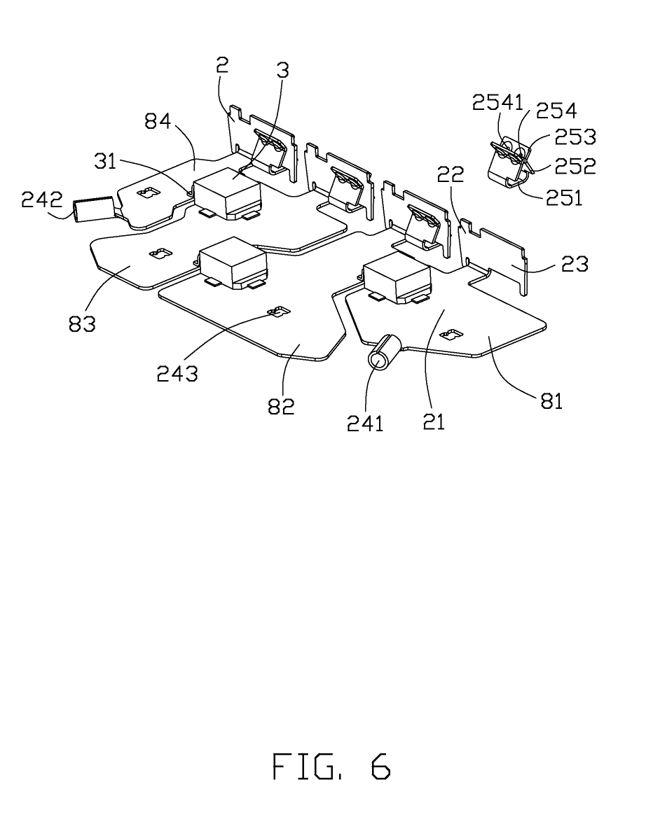

Referring to FIGS. 4-6, the terminal 2 is mounted in the case 12 and comprises a first terminal 81, a second terminal 82, a third terminal 83 and the fourth terminal 84 in turn along the right-to-left direction. Each of the terminals 81, 82, 83, 84 has a planar main body 21, a bending portion 22 bent upwardly from a rear end of the main body 21 and having a mounting portion 23 for connecting to a conductive foil (not shown) of the solar panel.

The bending portion 22 is planar upright piece substantially in a rectangular shape and extends along a right-to-left direction, and the mounting portion 23 is a right part of the bending portion 22 and disconnects with the main body 21. The main body 21 defines a plurality of positing holes 243 passing through the main body 21 in an upper-to-bottom direction, and the positioning posts 1202 of the case 12 insert into the positioning holes 243 to retain the terminals 81, 82, 83, 84. The diode 3 are disposed between two adjacent main bodies 21 and has legs 31 extending horizontally thereof to be soldered to the main bodies 21. Two banding portions 241, 242 extend forwardly from front edges of the main bodies 21 of the first and the fourth terminals 81, 84 to retain wires of the cables.

Usually, the first and the second terminals 81, 82 on the right near the positive input port 125 bring much more heats rather than the third and the fourth terminals 83, 24 near the negative output port 126, so total area of the first and the second terminals 81, 82 is bigger than that of the third and the fourth terminals 83, 84 in present embodiment. The first terminal 81 and the fourth terminal 84 are near outside so can radiate heats efficiently, the second terminal 82 and the third terminals 83 are located between the first and the fourth terminals 81, 84 and can not radiate heats efficiently, and the second terminal 82 is near the positive input port 125 thereby easily gathering heats.

The main bodies 21 of the terminals 2 are designed with different areas so as to disperse heats efficiently, exactly say, the main body 21 of the second terminal 82 is designed to be largest; the main body 21 of the third terminal 83 is near the negative output port 126, so the main body 21 of the third terminal 83 is designed to be larger which is smaller than the main body 21 of the second terminal 82 but larger than the main bodies 21 of the first and the fourth terminals 81, 84; the main body 21 of the third terminal 83 is small for it is near the outside; and the main body 21 of the fourth terminal 84 is smallest for it is both near the outside and the negative output port 126. That means a sequence of the terminals 2 based on the area of the main body 21 and arrayed from largest to smallest is: the second terminal 82, the third terminal 83, the first terminal 81 and the fourth terminal 84. And since the bending portions 22 of the terminals 2 substantially have an equal area, so in other words, a sequence of the terminals 2 based on the area thereof and arrayed from largest to smallest also is: the second terminal 82, the third terminal 83, the first terminal 81 and the fourth terminal 84. By above arrangement, heats produced in the PV junction box 100 can be dispersed efficiently so as to improve a using life of the PV junction box 100.

The clamper 25 has a horizontal planar base 251, two elastic arms 252 bent upwardly from a front and a rear edge of the planar base 251 and extending inwardly toward each other, two free ends 253 bent outwardly to leave each other and two clamping portions 254 connecting the free ends 253 and the elastic arms 252. The mounting portion 23 of each terminal 2 is clamped by the two clamping portions 254. So that when the PV junction box 100 electrically connects to a conductive foil of the solar panel, the conductive foil is inserted between and clamped by the clamping portion 254 and the mounting portion 23 to electrically connect with the mounting portion 23 of each terminal 2.

In present embodiment, the clamping portion 24 has a plurality of depresses 2541 in an inner surface thereof and arrayed in the right-to-left direction, so that the clamping portion 24 can connect to the mounting portion 23 from line contacting manner to multi-point contacting manner to ensure the conductive foil (not shown) reliably contacts with the mounting portion 23.

When assembly, the terminals 2 with diodes 3 and clamper 25 are retained to the bottom wall 120 of the case 12, the lid 11 are tied to the case 12 by the tying rope 17 and then covers the case 12 from a top side, with the latching arms 114 locking with the latching grooves 1211 of the case 11 and the sealing ring 13 sandwiched between the lid 11 and the case 12. The adhesive film 14 is mounted to the bottom of the case 12, and the sleeve 15 is assembled to the assembling portion 128.

While a preferred embodiment in accordance with the present invention has been shown and described, equivalent modifications and changes known to persons skilled in the art according to the spirit of the present invention are considered within the scope of the present invention as described in the appended claims.

What is claimed is:

1. A PV (photovoltaic) junction box comprising:
a case having a bottom wall and a plurality of sidewalls located on a peripheral of the bottom wall and defining a receiving cavity cooperatively with the bottom wall, the sidewalls comprising a front wall extending along a right-to-left direction and two planar connecting sidewalls located on two opposite sides of the front wall along the right-to-left direction and connecting with the front wall, respectively; the connecting sidewall aslant disposed relative to the front wall, and the case having an assembling portion outwardly and vertically protruding from each of the connecting sidewall;
a lid covering the case; and
a plurality terminals received in the receiving cavity of the case.

2. The PV junction box as claimed in claim 1, wherein the front wall is located in a front of the connecting sidewalls, the assembling portion is integrated formed with the case and defines a port of the case for a cable passing through.

3. The PV junction box as claimed in claim 2, wherein the sidewalls comprise a pair of first sidewalls parallel to each other and extending along the front-to-back direction, a pair of second sidewalls parallel to each other and extending along a right-to-left direction, one of the second sidewall located in the front of the case is the front wall, and the connecting sidewalls aslant connects the front wall and the two first sidewalls.

4. The PV junction box as claimed in claim 2, wherein the connecting sidewalls are symmetrically disposed and each defines a 45 degrees angle with respective to both the front-to-back direction and the right-to-left direction.

5. The PV junction box as claimed in claim 2, wherein the lid has a top wall and a plurality of side walls extending downwardly from a peripheral of the top wall, the side walls are formed with a plurality of latching arms to lock with a plurality of latching holes provide on the sidewalls of the case.

6. The PV junction box as claimed in claim 5, further comprising sleeves assembled to the assembling portions, the assembling portion defines outer thread, and the sleeve defines inner thread to engage with the outer thread of the assembling portion.

7. The PV junction box as claimed in claim 6, wherein the terminals comprise a first terminal, a second terminal, a third terminal and the fourth terminal, the second and the third terminals are disposed between the first and the fourth terminals, and near the first and the fourth terminals, respectively, each terminal has a planar main body mounted to the bottom wall of the case, a sequence of the terminals based on areas of the main bodies thereof and arrayed from largest to smallest is: the second terminal, the third terminal, the first terminal and the fourth terminal.

8. The PV junction box as claimed in claim 1, wherein the assembling portion is separated from the case and attached to the connecting sidewall in a face-to-face manner.

9. A PV (photovoltaic) junction box comprising:
a case having a bottom wall and a plurality of sidewalls located on a peripheral of the bottom wall and defining a receiving cavity cooperatively with the bottom wall, the case defining a transverse axis and a longitudinal axis, the cases having two assembling portions protruding outwardly from at least one of the sidewall and each defining a port for a cable passing through, the assembling portions symmetrically disposed relative to the transverse axis of the case, and aslant disposed with respective to both the a transverse axis and the longitudinal axis; and
a plurality terminals mounted to the case.

10. The PV junction box as claimed in claim 9, wherein the assembling portions extend away from each other.

11. The PV junction box as claimed in claim 10, wherein the sidewall comprises a pair of first sidewalls parallel to each other and extending along a transverse direction, a pair of second sidewalls parallel to each other and extending along a longitudinal direction, and two planar connecting sidewalls aslant connects one of the second wall located on the front of the case and the two first sidewalls.

12. The PV junction box as claimed in claim 11, wherein the assembling portion vertically and outwardly extends from the connecting sidewall.

13. The PV junction box as claimed in claim 12, wherein the assembling portion is integrated formed with the connecting sidewall.

14. The PV junction box as claimed in claim 13, wherein each terminal has a main body, the main body has a through positioning hole, and the bottom wall of the case is provided with a post inserting into the positioning hole to retain the terminal.

15. The PV junction box as claimed in claim 13, further comprising a lid, the lid defines a first hole at a rear end thereof, and the case defines a corresponding second hole outside the receiving cavity, a tying rope passes through the first and the second holes to tie the lid and the case together.

16. A PV junction box comprising:
a case defining a defining a rectangular configuration defining a pair of opposite long sides and a pair of short sides with a pair of chamfered structures on two corners along one long side;
a plurality of terminals disposed in the case; and
positive and negative ports formed on said pair of chamfered structures, respectively, for respective communication with an exterior to the corresponding terminals; wherein
said chamfered structure is not angled with the adjacent long side and short side at forty-five degrees but more tilted toward the adjacent long side so as to have axes defined by the corresponding positive and native ports intersected with each other around a position where a centerline of the long side extends.

17. The PV junction box as claimed in claim 16, wherein an amount of said terminals are four including two inner ones and two outer ones under condition that said two outer ones define corresponding chamfered mechanisms in compliance with the corresponding chamfered structures to connect to the corresponding positive port and negative port.
